(19) United States
(12) Patent Application Publication
(10) Pub. No.: US 2008/0258193 A1
(43) Pub. Date: Oct. 23, 2008

(54) FERROELECTRIC MEMORY AND METHOD OF MANUFACTURING THE SAME

(76) Inventors: Koji Yamakawa, Tokyo (JP); Soichi Yamazaki, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/107,230

(22) Filed: Apr. 22, 2008

(30) Foreign Application Priority Data
Apr. 23, 2007 (JP) 2007-112902

(51) Int. Cl. H01L 29/92; H01L 21/02

(52) U.S. Cl. 257/295; 438/3; 257/E21.009; 257/E29.342

(57) ABSTRACT

A ferroelectric memory that stores information by using a hysteresis characteristic of a ferroelectric, has a semiconductor substrate; a lower electrode formed above said semiconductor substrate; a ferroelectric film formed on said lower electrode; and an upper electrode formed on said ferroelectric film, wherein said upper electrode includes an AOₓ-type conductive oxide film formed on said ferroelectric film and an “A” metal film formed on said AOₓ-type conductive oxide film, and said “A” metal is a noble metal selected from among Ir, Ru, Rh, Pt, Os and Pd.

### CROSS-REFERENCE TO RELATED APPLICATION

This application is based upon and claims the benefit of priority from the prior Japanese Patent Application No. 2007-112902, filed on Apr. 23, 2007, the entire contents of which are incorporated herein by reference.

### BACKGROUND OF THE INVENTION

1. Field of the Invention

The present invention relates to a ferroelectric memory that stores information by using a hysteresis characteristic of a ferroelectric and a method of manufacturing the same.

2. Background Art

In recent years, there have been developed ferroelectric random access memories (FeRAMs), which are nonvolatile memories that use a ferroelectric film that provides advantages, such as low power consumption, high integration, high-speed operation, high endurance, non-volatility and random accessibility.

The FeRAM uses a ferroelectric film such as of PZT (Pb(ZrₓTi₁₋ₓ)O₃), BIT (Bi₄Ti₃O₁₂) and SBT (SrBi₂Ta₂O₉) in the capacitor part. Such a ferroelectric film has a crystal structure based on the perovskite structure, which is basically an oxygen octahedron. Thus, the ferroelectric film has a residual polarization, and the residual polarization provides the non-volatility of the FeRAM.

The ferroelectric film is formed by sputtering, MOCVD, a sol-gel process or the like, which are consistent with the semiconductor memory manufacturing process.

The ferroelectric film of PZT or the like is crystallized on the lower electrode, and therefore, the material or crystal structure of the lower electrode has a significant effect on the ferroelectric film.

The material or structure of the upper electrode has a significant effect on the characteristics of the capacitor and in particular has a direct effect on the degradation of the capacitor during the semiconductor memory manufacturing process, the reliability of the ferroelectric capacitor or the like.

The temporal changes of the leakage characteristics, the C-V characteristics, the polarization characteristics and the electrical characteristics, the retention characteristics, the fatigue characteristics and the like of the capacitor closely relate to the materials and structures of the electrodes.

Typically, the upper electrode is made of a noble metal, such as Pt, Ir and Ru, a noble metal oxide, such as IrO₂ and RuO₂, or a conductive composite oxide having the perovskite structure, such as SrRuO₃, LaNiO₃ and (La, Sr)CoO₃. In particular, IrO₂ is most commonly used for the upper electrode. IrO₂ is deposited on a PZT film by chemical sputtering using an Ir target.

As the size of the capacitor becomes smaller from conventional several micron square to submicron square, the capacitor becomes more susceptible to process damage from CVD of a mask for capacitor processing, RIE for capacitor processing, CVD of an interlayer insulating film or the like. Therefore, there is a demand for improvement of the process damage resistance by modification of the upper electrode.

Thus, in order to improve the integration of FeRAMs using a ferroelectric material, the decrease in device reliability due to the increase in process damage due to the decrease in capacitor cell area has to be compensated for.

A reduction damage to a capacitor 100b is that the polarization reversal of a ferroelectric is prevented. The polarization reversal of a ferroelectric is prevented by a fixed charge formed in the capacitor or at the electrode interface as a result of hydrogen or the like being trapped in the ferroelectric or at the interface between the ferroelectric film and the electrode or an oxygen deficiency occurring in the ferroelectric structure. The polarization reversal can occur during CVD for forming a SiOₓ hard mask used in processing of the capacitor, CVD of an interlayer insulating film, or processing of the capacitor.

In particular, as the size of the capacitor 100b becomes smaller, the ratio of the reduction damage originating from the perimeter of the capacitor increases, and the reduction damage causes a degradation of the polarization. In addition, the reduction damage causes a degradation of a polarization reversal charge amount of the capacitor (a fatigue degradation), a degradation of the polarization retention (a retention degradation), and imprint of the ease of polarization in the polarization writing direction or prevention of the polarization reversal in the opposite direction (an imprint degradation), for example.

In addition, a metal electrode material that has a high hydrogen permeability also easily causes a defect in the capacitor and the electrode interface.

Thus, the degree of the process damage largely depends on the choice of the upper electrode material.

As described above, in order to improve reduction process resistance of the capacitor, an IrOₓ film is formed as the upper electrode. In this case, since the IrOₓ film is an oxide film, there is a problem that the contact between the IrOₓ film and wiring formed thereon is degraded by the heat in a subsequent step of forming or annealing the wiring or an insulating film. The degradation is considered to be because oxygen in the IrOₓ is dissociated and combined with the material of the wiring, such as TiN, W, Al and Cu, to form an oxide. In addition, a morphology degradation of the surface of the IrOₓ film (a growth of IrOₓ crystal grains, evaporation of part of IrOₓ, or the like) caused by a thermal process can cause a degradation of the capacitor or the contact.

In addition, as described above, the IrOₓ film is formed by chemical sputtering using an Ir target in an atmosphere containing oxygen. There is a problem that many particles are produced when the film is formed by chemical sputtering. Those particles can cause a defect of a micro capacitor.

There has been proposed a method of manufacturing a semiconductor device in which an IrOₓ film containing a microcrystal formed at the same time as the formation of the film is formed on a ferroelectric, and then, an IrOₓ film containing a columnar crystal is formed as an upper electrode (see Japanese Patent Laid-Open No. 2006-73648, for example).

According to the conventional technique, the degradation of the characteristics of the ferroelectric caused by the reaction between the upper part of the ferroelectric film and the upper electrode when the upper electrode is formed is prevented.

However, according to the conventional technique, since the upper part of the upper electrode is the IrOₓ film, the contact described above can be degraded, and particles can be produced when the film is formed by chemical sputtering.

### SUMMARY OF THE INVENTION

According to one aspect of the present invention, there is provided: a ferroelectric memory that stores information by using a hysteresis characteristic of a ferroelectric, comprising:

a semiconductor substrate;

a lower electrode formed above said semiconductor substrate;

a ferroelectric film formed on said lower electrode; and

an upper electrode formed on said ferroelectric film,

wherein said upper electrode includes an AOₓ-type conductive oxide film formed on said ferroelectric film and an “A” metal film formed on said AOₓ-type conductive oxide film, and

said “A” metal is a noble metal selected from among Ir, Ru, Rh, Pt, Os and Pd.

According to the other aspect of the present invention, there is provided: a ferroelectric memory that stores information by using a hysteresis characteristic of a ferroelectric, comprising:

a semiconductor substrate;

a lower electrode formed above said semiconductor substrate;

a ferroelectric film formed on said lower electrode; and

an upper electrode formed on said ferroelectric film,

wherein said upper electrode includes a first AOₓ-type conductive oxide film formed on said ferroelectric film and a second AOₓ-type conductive oxide film formed on said first AOₓ-type conductive oxide film,

said second AOₓ-type conductive oxide film has a higher “A” metal concentration than said first AOₓ-type conductive oxide film, and

said “A” metal is a noble metal selected from among Ir, Ru, Rh, Pt, Os and Pd.

According to further aspect of the present invention, there is provided: a method of manufacturing a ferroelectric memory that stores information by using a hysteresis characteristic of a ferroelectric, comprising:

forming a lower electrode above a semiconductor substrate;

forming a ferroelectric film on said lower electrode; and

forming an upper electrode on said ferroelectric film by

forming an AOₓ-type conductive oxide film by chemical sputtering,

wherein an “A” metal is a noble metal selected from among Ir, Ru, Rh, Pt, Os and Pd, and

sputtering of the “A” metal is carried out in a same chamber as the chamber used for said chemical sputtering after said chemical sputtering.

According to still further aspect of the present invention, there is provided: A method of manufacturing a ferroelectric memory that stores information by using a hysteresis characteristic of a ferroelectric, comprising:

forming a lower electrode above a semiconductor substrate;

forming a ferroelectric film on said lower electrode; and

forming an upper electrode on said ferroelectric film by forming a first AOₓ-type conductive oxide film on said ferroelectric film and forming a second AOₓ-type conductive oxide film on said first AOₓ-type conductive oxide film

wherein an “A” metal is a noble metal selected from among Ir, Ru, Rh, Pt, Os and Pd.

### BRIEF DESCRIPTION OF THE DRAWINGS

FIG. 1 is a cross-sectional view showing a memory cell in a step of a method of manufacturing a ferroelectric memory according to the embodiment 1 of the present invention;

FIG. 2 is a cross-sectional view showing a memory cell in a step of a method of manufacturing a ferroelectric memory according to the embodiment 1 of the present invention, is continuous from FIG. 1;

FIG. 3 is a cross-sectional view showing a memory cell in a step of a method of manufacturing a ferroelectric memory according to the embodiment 1 of the present invention, is continuous from FIG. 2;

FIG. 4 is a cross-sectional view showing a memory cell in a step of a method of manufacturing a ferroelectric memory according to the embodiment 1 of the present invention, is continuous from FIG. 3;

FIG. 5 is a cross-sectional view showing a memory cell in a step of a method of manufacturing a ferroelectric memory according to the embodiment 1 of the present invention, is continuous from FIG. 4;

FIG. 6 is a cross-sectional view showing a memory cell in a step of a method of manufacturing a ferroelectric memory according to the embodiment 1 of the present invention, is continuous from FIG. 5;

FIG. 7 is a cross-sectional view showing a memory cell in a step of a method of manufacturing a ferroelectric memory according to the embodiment 1 of the present invention, is continuous from FIG. 6;

FIG. 8 is a cross-sectional view showing a memory cell in a step of a method of manufacturing a ferroelectric memory according to the embodiment 1 of the present invention, is continuous from FIG. 7;

FIG. 9 is a cross-sectional view showing a memory cell in a step of a method of manufacturing a ferroelectric memory according to the embodiment 1 of the present invention, is continuous from FIG. 8;

FIG. 10 is a cross-sectional view showing a memory cell in a step of a method of manufacturing a ferroelectric memory according to the embodiment 1 of the present invention, is continuous from FIG. 9;

FIG. 11 is a cross-sectional view showing a memory cell in a step of a method of manufacturing a ferroelectric memory according to the embodiment 1 of the present invention, is continuous from FIG. 10;

FIG. 12 is a cross-sectional view of a memory cell of a ferroelectric memory (FeRAM) according to the embodiment 2 of the present invention, which is an aspect of the present invention;

FIG. 13 is a cross-sectional view of a memory cell in a step in the method of manufacturing the ferroelectric memory according to the embodiment 2 of the present invention; and

FIG. 14 is a cross-sectional view of a memory cell in a step in the method of manufacturing the ferroelectric memory according to the embodiment 2 of the present invention, is continuous from FIG. 13.

### DETAILED DESCRIPTION

In the following, embodiments of the present invention will be described with reference to the drawings.

### Embodiment 1

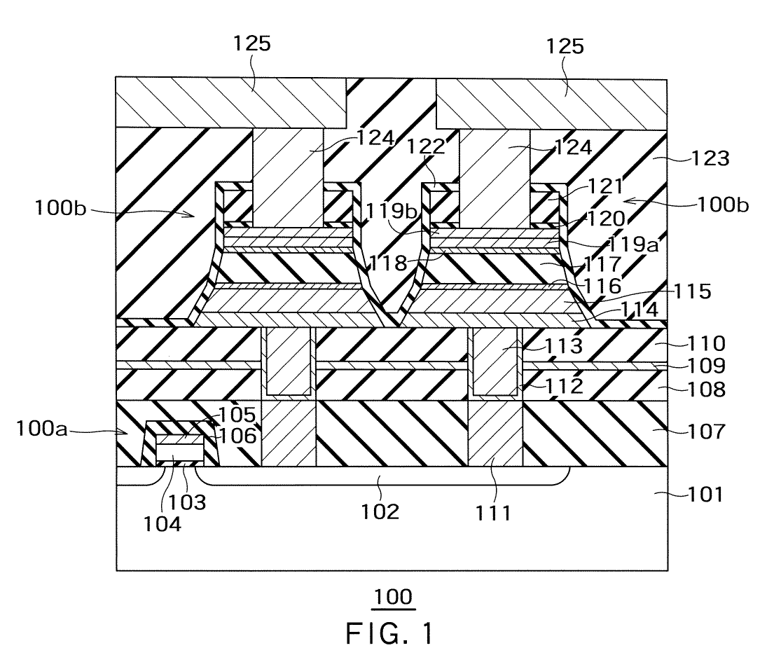

FIG. 1 is a cross-sectional view of a memory cell of a ferroelectric memory (FeRAM) according to an embodiment 1 of the present invention, which is an aspect of the present invention.

As shown in FIG. 1, on a silicon substrate (a semiconductor substrate) 101 of a ferroelectric memory 100, a source/drain diffusion layer 102 is formed. A gate insulating film 103 is also formed on the silicon substrate 101. A gate electrode (a polycide structure composed of a polysilicon film 104 and a WSi₂ film 105, for example) that serves as a word line is formed on the gate insulating film 103. A gate cap film and a gate side wall film 106 formed by a silicon nitride film are formed to surround the gate electrode. These components constitute a MOS transistor 100a. In addition, a groove-shaped device isolation film (not shown) is also formed on the silicon substrate 101.

In addition, a first interlayer insulating film 107 (a silicon oxide film) is formed to surround the MOS transistor 100a.

In addition, on the first interlayer insulating film 107 planarized, a second interlayer insulating film 108 (a silicon oxide film), a third interlayer insulating film 109 (a silicon nitride film) and a fourth interlayer insulating film 110 (a silicon oxide film) are formed. A contact plug 111 and a tungsten plug 113 that connect an activation region 102 of the transistor and a barrier layer 114 of a capacitor (a capacitor barrier layer) to each other are formed in the first, second, third and fourth interlayer insulating films 107, 108, 109 and 110. The barrier layer 114 prevents oxidation of the surface of the tungsten plug 113 during an annealing process in oxygen for ensuring capacitor characteristics. The barrier layer 114 is a TiAlN film in this embodiment, for example.

In addition, a diffusion barrier film (a contact barrier film) 112 is formed to surround the tungsten plug 113.

In addition, a capacitor 100b is formed on the fourth interlayer insulating film 110. The capacitor 100b has the barrier layer 114 described above, a lower electrode 115 formed on the barrier layer 114, a first SRO film 116, which is an ABO₃ perovskite-type conductive oxide film formed on the lower electrode 115, a ferroelectric film 117 formed on the first SRO film 116, a second SRO film 118, which is an ABO₃-perovskite-type conductive oxide film formed on the ferroelectric film 117, a first upper electrode part 119a formed on the second SRO film, and a second upper electrode part 119b formed on the first upper electrode part 119a.

The lower electrode 115 is formed by an Ir film, for example.

The material of the ferroelectric film 117 is selected from among PZT (Pb(ZrₓTi₁₋ₓ)O₃), BIT (Bi₄Ti₃O₁₂) and SBT (SrBi₂Ta₂O₉), for example.

The first upper electrode part 119a is formed by an AOₓ-type conductive oxide film. The second upper electrode part 119b is formed by an “A” metal film. The “A” metal is a noble metal selected from among Ir, Ru, Rh, Pt, Os and Pd. That is, the AOₓ-type conductive oxides that can be used for the first upper electrode part 119a include noble metal oxides, such as PtOₓ, IrOₓ, RuOₓ, RhOₓ and OsOₓ, solid solutions thereof, mixtures thereof, and substances containing the noble metal oxides as a primary component and doped with another element. In addition to the noble metal oxides, conductive oxides, such as ReO₃, VOₓ, TiOₓ, InOₓ, SnOₓ, ZnOₓ and NiOₓ, can be used as the AOₓ-type conductive oxide forming the upper electrode.

As an alternative to SrRuO₃ (SRO) described above, LaNiO₃ (LNO) or (La, Sr)CoO₃ can also be used for the ABOₓ perovskite-type conductive oxide film, for example. As an alternative to the ABOₓ perovskite-type conductive oxide film, YBCO (a superconductor) can also be used. The character “B” in the ABO₃ perovskite-type conductive oxide film refers to a metal.

On the second upper electrode part 119b, a first mask film (an Al₂O₃ film) 120 and a second mask film (a SiO₂ film) 121 for processing the upper electrode are formed.

In addition, a hydrogen barrier film 122 is formed to surround the whole of the capacitor 100b. A fifth interlayer insulating film (a silicon oxide film) 123 is formed on the hydrogen barrier film 122, and a contact 124 and wiring 125 for connecting the upper electrodes of adjacent capacitors 100b to each other are formed in the fifth interlayer insulating film 123. The contact 124 is made of the material of the wiring, such as TiN, W, Al and Cu.

Now, there will be discussed a reason why the upper electrode is composed of an IrOₓ film (the first upper electrode part) having a high oxygen concentration in the vicinity of the interface with the ferroelectric film and an Ir film (the second upper electrode part) formed thereon. In the following, a case where the upper electrode is made of IrOₓ will be described as an example.

Structural characteristics, such as particle size, density, composition, crystal structure and crystal orientation, and electrical characteristics, such as sheet resistance, of IrOₓ vary depending on the film deposition conditions. When IrOₓ is used for the upper electrode of the ferroelectric capacitor, the resistance to reduction process damage via the upper electrode (such as damage from CVD of an insulating film or mask material, RIE for capacitor processing, CVD or RIE of an interlayer insulating film, sintering in a reducing atmosphere or the like) depends on these parameters. For example, a dense Ir film or a film having an IrO₂ crystal structure has high hydrogen barrier effect, and the reduction resistance of the capacitor is improved.

The IrOₓ film is typically formed by chemical sputtering using an Ir target in an Ar/O₂ atmosphere. In this case, if an Ir target having a diameter of about 300 mm is used, and a sputtering power of about 2 kW is applied, the amount of oxygen in the formed film (the Ir/O ratio of the formed film) can be easily changed. Alternatively, under a sputtering condition that the sputtering power is lower than about 2 kW, the same composition and crystal characteristics as described above can be achieved by reducing the amount of oxygen. Since the surface of the Ir target is less susceptible to oxidation, the amount of oxygen in the film can be significantly changed by adjusting the Ar/O₂ ratio during sputtering. An IrO₂ film that has a stoichiometric composition can be adequately formed under the conditions that the sputtering power is equal to or lower than 2 kW, and the Ar/O₂ ratio of the atmospheric gas is about 2 to 1, for example. If the amount of Ar is further increased, further Ir is captured, and an IrOₓ film having higher density is formed.

In terms of the reduction resistance and the hydrogen barrier effect, the higher the density, the more advantageous the IrOₓ film is. Therefore, a film having a composition in which the Ir concentration is higher than that of IrO₂ having the stoichiometric composition is preferably formed.

However, for the electrode of the ferroelectric capacitor, ensuring a sufficient amount of oxygen is important to achieve the initial hysteresis characteristics (the residual polarization, the squareness ratio or the like) and the capacitor reliability (the fatigue characteristics, the imprint characteristics, the retention characteristics or the like). Therefore, an IrOₓ film having a higher amount of oxygen than the film of the stoichiometric composition (IrO₂) formed under a condition that the oxygen concentration is high is preferable.

As described above, it is preferable that, as the upper electrode of the ferroelectric capacitor, an IrOₓ film (the first upper electrode part) having a high oxygen concentration is formed in the vicinity of the interface with the ferroelectric film, and an Ir film, a film of the stoichiometric composition (IrO₂) or an IrOₓ film having a high Ir concentration (the second upper electrode part) is formed thereon.

As described above, an ABO₃ perovskite-type conductive oxide film 118 can be formed to compensate for an oxygen deficiency at the interface between the upper electrode and the ferroelectric film.

Generally, when an IrOₓ film is formed, a large amount of particles are produced. If the particles exist on the device, a wire break or a short-circuit can occur in the circuit, or an unwanted capacitor can be formed. However, if a film of the stoichiometric composition (IrO₂) or a film having a high Ir concentration is formed with a high sputtering power after the IrOₓ film is formed by sputtering, occurrence of the particles can be reduced. This can be considered to be because the surface of the Ir target is modified.

Now, a method of manufacturing the ferroelectric memory 100 having the configuration described above will be described. In the following, in particular, the configuration of the capacitor will be described in detail. As the “A” metal, Ir is used.

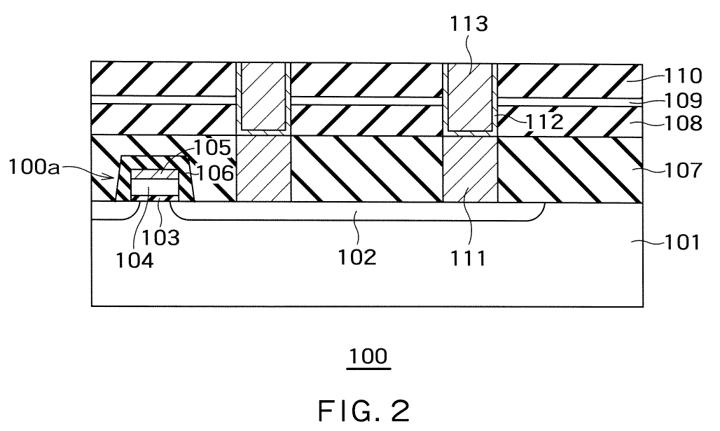

FIGS. 2 to 11 are cross-sectional views showing a memory cell in different steps of a method of manufacturing a ferroelectric memory according to the embodiment 1 of the present invention.

As shown in FIG. 2, the MOS transistor 100a is formed on the silicon substrate (the semiconductor substrate) 101. Then, the contact plug 111 and the tungsten plug 113 that connects the activation region 102 of the transistor and the barrier layer 114 of the capacitor to each other are formed in the first, second, third and fourth interlayer insulating films 107, 108, 109 and 110.

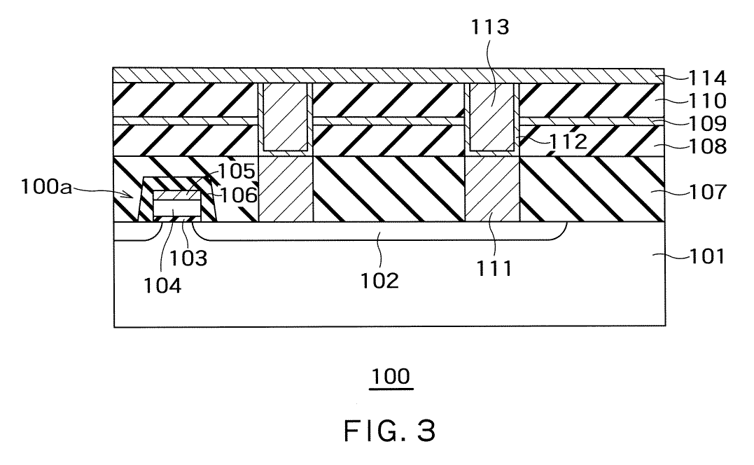

Then, in a region including at least the top surface of the tungsten plug 113, the barrier layer 114 is formed by DC magnetron sputtering (FIG. 3).

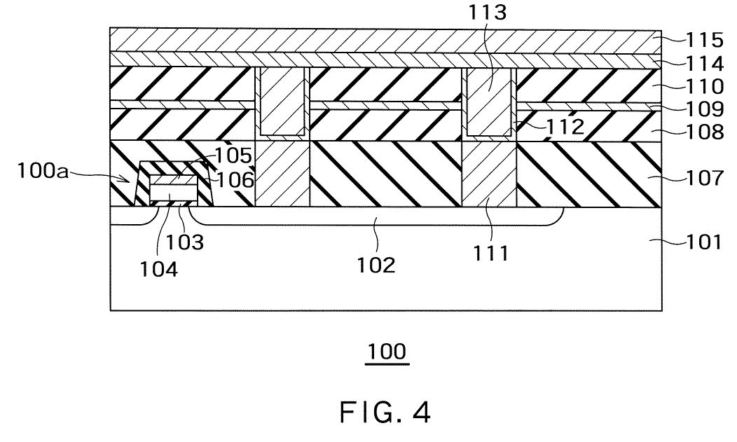

Then, on the barrier layer 114, the lower electrode 115, which is formed by an Ir film, for example, is formed by sputtering (FIG. 4).

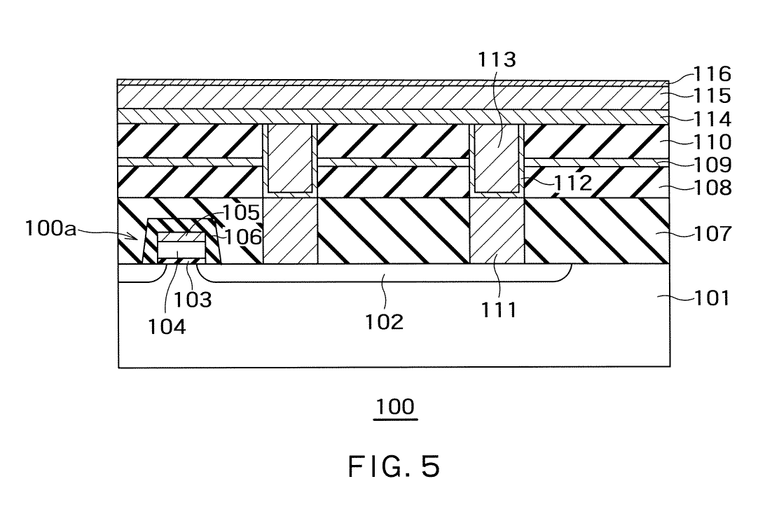

Then, on the lower electrode 115, the first SRO (SrRuO₃) film 116 is formed by DC magnetron sputtering using a conductive SRO ceramic target (FIG. 5). Typical sputtering conditions are that the atmosphere is Ar, the pressure is 0.5 Pa, the substrate is not heated, and the sputtering power is 1 kW. Under the conditions, an amorphous SRO film having a thickness of about 10 to 50 nm is formed. After the sputtering, the film formed by the sputtering is heated by RTA in an oxygen atmosphere at 550 to 650 degrees C., thereby crystallizing the first SRO film 116.

A defect, such as oxygen deficiency, at the interface between PZT and the upper electrode has a significant effect on the subsequent capacitor fabrication process, such as a reduction process damage resistance, a fatigue characteristics degradation, a retention degradation and an imprint degradation. Therefore, a sufficient amount of oxygen has to be supplied to the interface between the PZT film and the upper electrode. The thickness of the SRO film described above is determined in such a manner that a sufficient amount of oxygen is supplied to interface between the PZT film and the upper electrode.

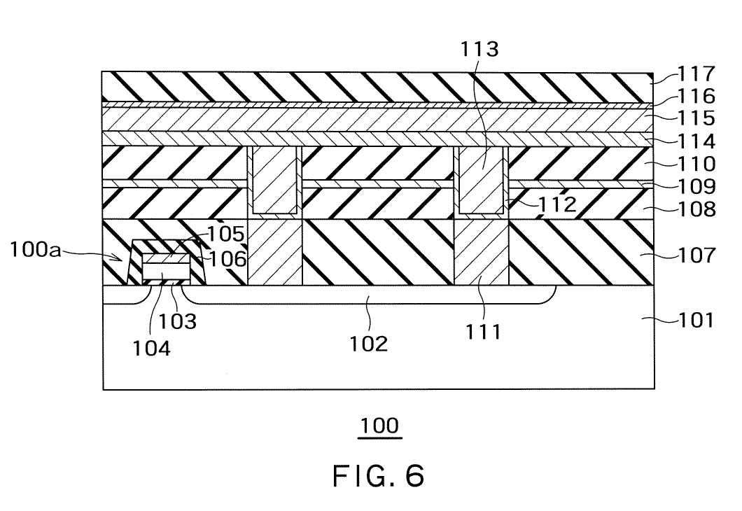

Then, on the first SRO film 116, the ferroelectric film 117, which is a PZT film, for example, is formed by RF magnetron sputtering (FIG. 6). In this embodiment, a PZT ceramic target in which the amount of Pb is increased by about 10% is used. The composition of the target is Pb_{1.10}La_{0.05}Zr_{0.4}Ti_{0.6}O₃. The PZT ceramic target allows high sputtering speed and has high resistance to environment, such as water, if the PZT ceramic target has a high density. Therefore, as the PZT ceramic target, a ceramic sintered body having a theoretical density of 98% or higher is used.

During sputtering, the temperature of the substrate increases by the action of plasma, or bombardment of the substrate with flying particles occurs. As a result, it is likely that evaporation of Pb from the Si substrate or resputtering occurs, and a deficiency in Pb in the film occurs. The excess amount of Pb in the target is intended to compensate for such a deficiency and to promote crystallization of the PZT film by RTA. Other elements including Zr, Ti and La are captured in the film at substantially the same ratio as that of the composition of the target, and therefore, a target having a desired composition can be used.

If the electrical characteristics are unstable due to the composition of the PZT film or the like, the conditions for forming the amorphous PZT film are changed. For example, to improve the structural or electrical characteristics of the PZT film to be crystallized, sputtering that involves introducing oxygen is used.

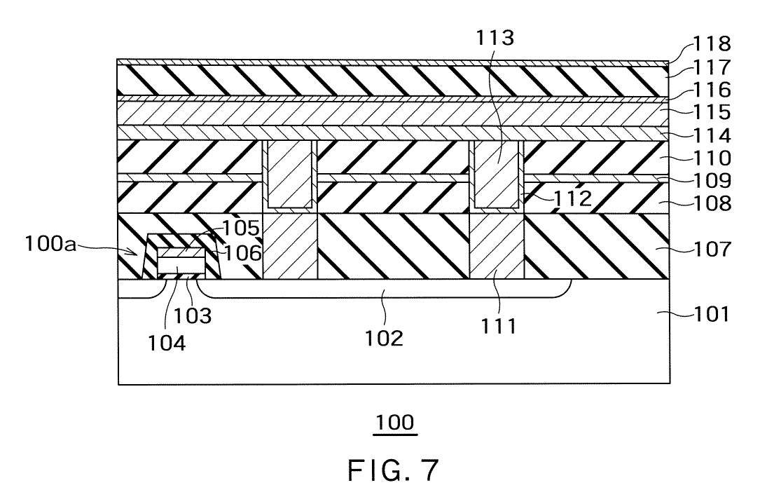

Then, on the ferroelectric film 117 (the crystallized PZT film in this embodiment), the second SRO (SrRuO₃) film 118 is formed by DC magnetron sputtering using a conductive SRO ceramic target (FIG. 7). As with the first SRO film 116, for example, an amorphous SRO film having a thickness of about 10 to 50 nm is formed under the conditions that the atmosphere is Ar, the pressure is 0.5 Pa, the substrate is not heated, and the sputtering power is 1 kW. After the sputtering, the film formed by the sputtering is heated by RTA in an oxygen atmosphere at 550 to 650 degrees C., thereby crystallizing the second SRO film 118.

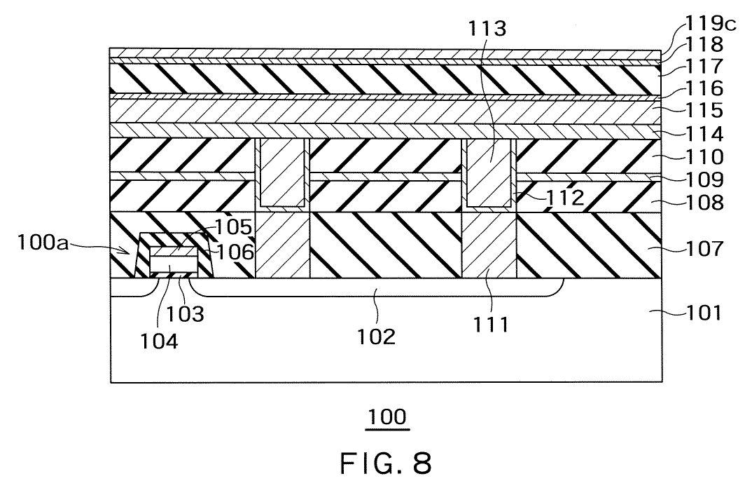

Then, on the second SRO film 118, an IrOₓ film (a film having a higher oxygen concentration than IrO₂) constituting the first upper electrode part 119a is formed by DC magnetron sputtering (FIG. 8). The DC magnetron sputtering is carried out in an Ar/O₂ atmosphere at room temperature by applying a sputtering power of 1 kW, for example, to an Ir target having a diameter of 300 mm.

The IrOₓ film is preferably formed at room temperature or a temperature equal to or lower than 100 degrees C. After the IrOₓ film is formed, the IrOₓ is crystallized by RTO at a temperature from 400 to 600 degrees C., preferably at a temperature of 500 degrees C. This thermal process is intended not only to crystallize IrOₓ but also to form a PZT/IrOₓ interface.

As described above, by using the IrOₓ film having a higher oxygen concentration than IrO₂, desired initial hysteresis characteristics (residual polarization, squareness ratio or the like) and capacitor reliability (fatigue characteristics, imprint characteristics and retention characteristics) can be achieved.

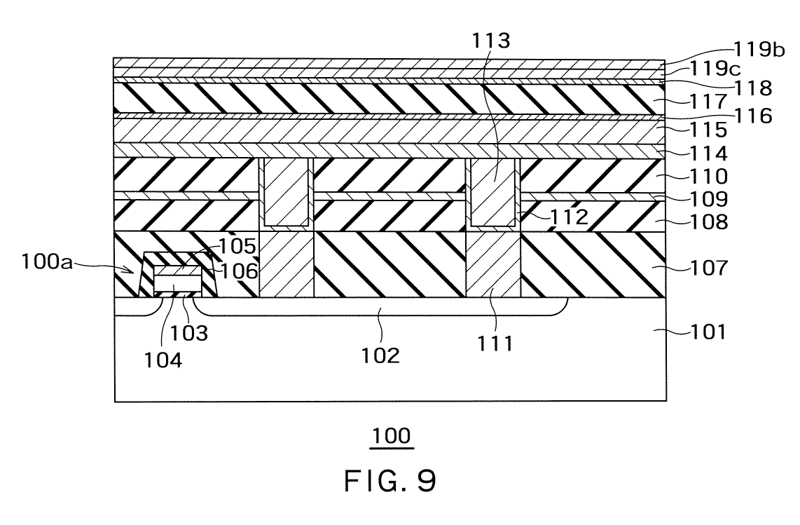

Then, on the first upper electrode part 119a, an Ir film constituting the second upper electrode part 119b is formed by DC magnetron sputtering (FIG. 9). The DC magnetron sputtering is carried out in an Ar atmosphere at room temperature by applying a sputtering power of 1 kW, for example, to an Ir target having a diameter of 300 mm.

By forming the Ir film, an IrOₓ/Ir structure is formed, and therefore, the connectivity between the upper electrode and the contact is improved, and a morphology change during a subsequent thermal processing of the IrOₓ film can be reduced.

In addition, since the Ir film is formed, the particles produced by the formation of the IrOₓ film are reduced, and the interior of the sputtering chamber is coated with Ir. As a result, the reproducibility in the subsequent IrOₓ film formation in the same chamber is improved.

To reduce the particles produced by the formation of the IrOₓ film, the upper electrode can also have a stack structure of IrOₓ/Ir, or dummy film can be formed to a shutter mechanism attached to the sputtering device when the Ir film is formed.

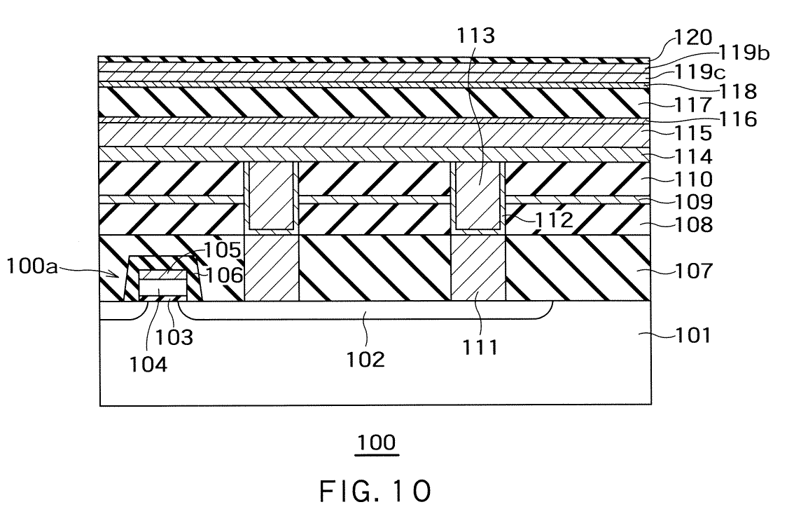

Then, on the second upper electrode part 119b, the first mask film (an Al₂O₃ film) 120, which is a hard mask, is formed by sputtering, for example (FIG. 10).

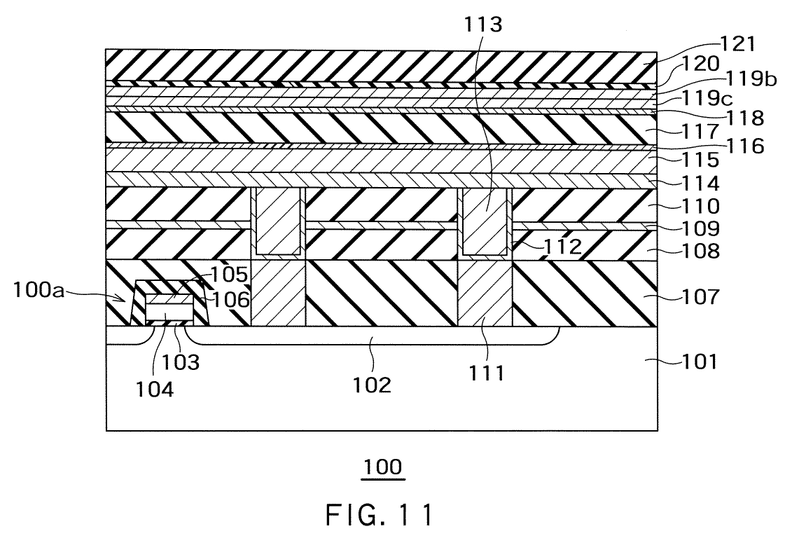

Then, on the first mask film 120, the second mask film (a SiO₂ film) 121, which is a hard mask, is formed by CVD, for example (FIG. 11).

As the mask material used when the capacitor 100b is processed by reactive ion etching (RIE), a photoresist can also be used, for example. However, the selectivity of the photoresist is limited, and the photoresist can hardly be used with high-temperature RIE, which is needed to increase the taper angle of the side surface of the capacitor 100b. For these reasons, the hard mask is used in this embodiment.

Then, using a photoresist (not shown), the first mask film 120 and the second mask film 121 are processed by RIE into a desired shape. In this case, the RIE processing is carried out at room temperature using a halogen-based gas, such as CHF₃ and CF₄.

Then, the photoresist is removed by ashing, and the first upper electrode part 119a and the second upper electrode part 119b are processed by RIE using the first mask film 120 and the second mask film 121. For example, a halogen gas is used for RIE processing of the Ir film and the IrO₂ film. The Ir film and the IrO₂ film of the upper electrode are processed by RIE by using a mixture gas of Cl₂, O₂, Ar or the like and heating the substrate to a high temperature of 250 to 400 degrees C. In the same way, the second SRO film 118 is also processed by RIE.

Then, using a mixture gas similarly mainly containing a halogen gas, such as Cl₂, CF₄, O₂ and Ar, the ferroelectric film 117 formed by a PZT film or the like is processed by high-temperature RIE.

Then, the first SRO film 116, the lower electrode 115 and the barrier layer 114 are processed by high-temperature RIE in the same process.

The thickness of the first mask film 120 and the second mask film 121, which are hard masks, is reduced as a result of RIE. Thus, the thickness or the like of the first and second mask films is determined to maintain the shape until the processing of the lower electrode and the like is completed. Once the RIE processing is completed, water rinsing is carried out, and the process of processing the capacitor is completed.

After that, the fifth interlayer insulating film 123 is formed, and then, the contact 124, the wiring 125 and the like are formed in a back-end process (a wiring process) to connect the capacitor 100b, the MOS transistor 100a and the like to each other.

By the process described above, the ferroelectric memory 100 described above and shown in FIG. 1 is completed.

As described above, for the ferroelectric memory according to this embodiment, and according to the method of manufacturing a ferroelectric memory according to this embodiment, the connectivity between the upper electrode and the contact can be improved while maintaining a desired polarization reversal characteristics of the ferroelectric film.

### Embodiment 2

In the embodiment 1 described above, the first upper electrode part is formed by an AOₓ-type conductive oxide film to achieve desired capacitor characteristics, and the second upper electrode part is formed by an “A” metal film to improve the hydrogen barrier effect and the connectivity with the contact.

As discussed in the embodiment 1, also in the case where the second upper electrode part is formed by an AOₓ-type conductive oxide film, the same advantages can be provided if the concentration of the “A” metal in the second upper electrode part is higher than at least that of the first upper electrode part.

Thus, in an embodiment 2, there will be described a case where the second upper electrode part is formed by an AOₓ-type conductive oxide film having an “A” metal concentration higher than that of the first upper electrode part.

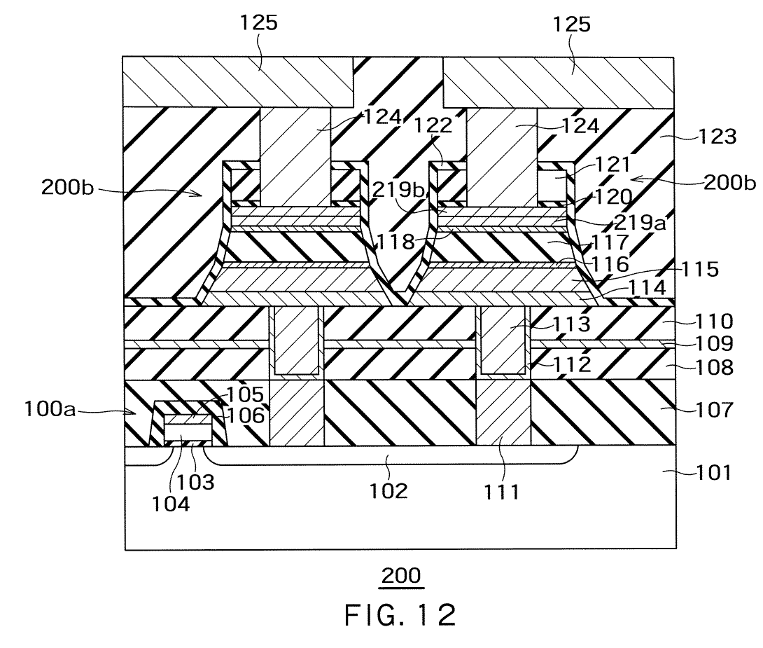

FIG. 12 is a cross-sectional view of a memory cell of a ferroelectric memory (FeRAM) according to the embodiment 2 of the present invention, which is an aspect of the present invention. In FIG. 12, the same reference numerals as those in FIG. 1 denote the same parts as those in the embodiment 1. That is, the ferroelectric memory according to this embodiment has the same configuration as the ferroelectric memory according to the embodiment 1 except for the first and second upper electrode parts.

As shown in FIG. 12, on a silicon substrate (a semiconductor substrate) 101 of a ferroelectric memory 200, as in the embodiment 1, a source/drain diffusion layer 102 is formed. A gate insulating film 103 is also formed on the silicon substrate 101. A gate electrode (a polycide structure composed of a polysilicon film 104 and a WSi₂ film 105, for example) that serves as a word line is formed on the gate insulating film 103. A gate cap film and a gate side wall film 106 formed by a silicon nitride film are formed to surround the gate electrode. These components constitute a MOS transistor 100a. In addition, a groove-shaped device isolation film (not shown) is also formed on the silicon substrate 101.

In addition, a first interlayer insulating film 107 (a silicon oxide film) is formed to surround the MOS transistor 100a.

In addition, on the first interlayer insulating film 107 planarized, a second interlayer insulating film 108 (a silicon oxide film), a third interlayer insulating film 109 (a silicon nitride film) and a fourth interlayer insulating film 110 (a silicon oxide film) are formed. A contact plug 111 and a tungsten plug 113 that connect an activation region 102 of the transistor and a barrier layer of a capacitor (a capacitor barrier layer) to each other are formed in the first, second, third and fourth interlayer insulating films 107, 108, 109 and 110. The barrier layer 114 prevents oxidation of the surface of the tungsten plug 113 during an annealing process in oxygen for ensuring capacitor characteristics. The barrier layer 114 is a TiAlN film in this embodiment, for example.

In addition, a diffusion barrier film (a contact barrier film) 112 is formed to surround the tungsten plug 113.

In addition, a capacitor 200b is formed on the fourth interlayer insulating film 110. The capacitor 200b has the barrier layer 114 described above, a lower electrode 115 formed on the barrier layer 114, a first SRO film 116, which is an ABO₃ perovskite-type conductive oxide film formed on the lower electrode 115, a ferroelectric film 117 formed on the first SRO film, a second SRO film 118, which is an ABO₃ perovskite-type conductive oxide film formed on the ferroelectric film 117, a first upper electrode part 219a formed on the second SRO film 118, and a second upper electrode part 219b formed on the first upper electrode part 219a.

The first upper electrode part 219a is formed by a first AOₓ-type conductive oxide film. The second upper electrode part 219b is formed by a second AOₓ-type conductive oxide film having an “A” metal concentration higher than that of the first AOₓ-type conductive oxide film. As in the embodiment 1, the “A” metal is a noble metal selected from among Ir, Ru, Rh, Pt, Os and Pd. That is, the AOₓ-type conductive oxides that can be used for the first upper electrode part 219a and the second upper electrode part 219b include noble metal oxides, such as PtOₓ, IrOₓ, RuOₓ, RhOₓ and OsOₓ, solid solutions thereof, mixtures thereof, and substances containing the noble metal oxides as a primary component and doped with another element.

In addition to the noble metal oxides, conductive oxides, such as ReO₃, VOₓ, TiOₓ, InOₓ, SnOₓ, ZnOₓ and NiOₓ, can be used as the AOₓ-type conductive oxide forming the upper electrode.

Now, a method of manufacturing the ferroelectric memory 200 having the configuration described above will be described.

In the method of manufacturing the ferroelectric memory according to the embodiment 2, all the steps excluding the steps of forming the upper electrode are the same as the steps shown in FIGS. 2 to 7, 10 and 11 described in the embodiment 1.

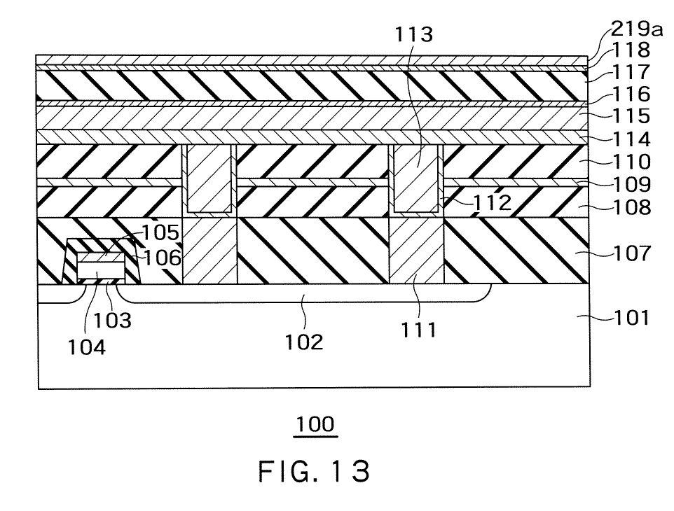

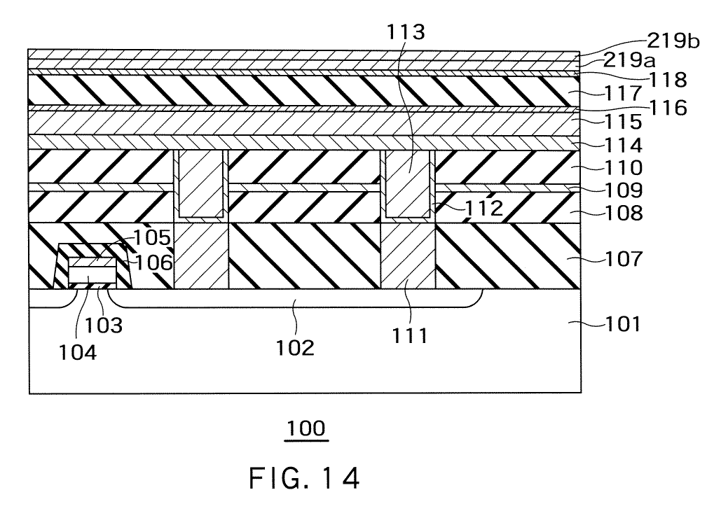

In the following, a configuration of the upper electrode will be described in particular. FIGS. 13 and 14 are cross-sectional views of a memory cell in different steps in the method of manufacturing the ferroelectric memory according to the embodiment 2 of the present invention. In these drawings, the same reference numerals as those in the embodiment 1 denote the same components as those in the embodiment 1.

As in the embodiment 1, first, in the steps shown in FIGS. 2 to 7, the barrier layer 114, the lower electrode 115, the first SRO film 116, the ferroelectric film 117 and the second SRO film 118 of the capacitor 200b are formed.

Then, on the second SRO film 118, an IrOₓ film (a film having a higher oxygen concentration than IrO₂) constituting the first upper electrode part (the first AOₓ-type conductive oxide film) 219a is formed by DC magnetron sputtering (FIG. 13). The DC magnetron sputtering is carried out in an Ar/O₂ atmosphere at room temperature by applying a sputtering power of 1 kW, for example, to an Ir target having a diameter of 300 mm.

The IrOₓ film is preferably formed at room temperature or a temperature equal to or lower than 100 degrees C. After the IrOₓ film is formed, the IrOₓ is crystallized by RTO at a temperature from 400 to 600 degrees C., preferably at a temperature of 500 degrees C. This thermal process is intended not only to crystallize IrOₓ but also to form a PZT/IrOₓ interface.

As described above, by using the IrOₓ film having a higher oxygen concentration than IrO₂, desired initial hysteresis characteristics (residual polarization, squareness ratio or the like) and capacitor reliability (fatigue characteristics, imprint characteristics and retention characteristics) can be achieved.

Then, on the first upper electrode part 219a, an IrOₓ film constituting the second upper electrode part 219b (the second AOₓ-type conductive oxide film) is formed by DC magnetron sputtering (FIG. 14). The DC magnetron sputtering is carried out in an Ar/O₂ atmosphere that has a lower oxygen concentration than in the formation of the first upper electrode part 219a at room temperature by applying a sputtering power of 1 kW, for example, to an Ir target having a diameter of 300 mm. Thus, the second upper electrode part 219b has a higher Ir concentration than the first upper electrode part 219a.

By forming the IrOₓ film having a higher Ir concentration, the connectivity between the upper electrode and the contact is improved, and a morphology change during a subsequent thermal processing of the IrOₓ film can be reduced.

In addition, as discussed in the embodiment 1, since the IrOₓ film having a higher Ir concentration is formed, the many particles produced by the formation of the IrOₓ film having a lower Ir concentration are reduced.

Then, in the same steps as those in the embodiment 1 shown in FIGS. 10 and 11, the first mask film 120 and the second mask film 121 are formed.

Then, as in the embodiment 1, using the first mask 120 and the second mask 121 processed by RIE into a predetermined shape, the first upper electrode part 219a, the second upper electrode part 219b, the second SRO film 118, the ferroelectric film 117, the first SRO film 116, the lower electrode 115 and the barrier layer 114 are processed by RIE. Once the RIE processing is completed, water rinsing is carried out, and the process of processing the capacitor is completed.

After that, as in the embodiment 1, the fifth interlayer insulating film 123 is formed, and then, the contact 124, the wiring 125 and the like are formed in a back-end process (a wiring process) to connect the capacitor 200b, the MOS transistor 100a and the like to each other.

By the process described above, the ferroelectric memory 200 described above and shown in FIG. 12 is completed.

As described above, for the ferroelectric memory according to this embodiment, and according to the method of manufacturing a ferroelectric memory according to this embodiment, the connectivity between the upper electrode and the contact can be improved while maintaining a desired polarization reversal characteristics of the ferroelectric film.

The present invention is not limited to the embodiments described above, and various variations can be appropriately made without departing from the spirit of the present invention.

What is claimed is:

1. A ferroelectric memory that stores information by using a hysteresis characteristic of a ferroelectric, comprising:
a semiconductor substrate;
a lower electrode formed above said semiconductor substrate;
a ferroelectric film formed on said lower electrode; and
an upper electrode formed on said ferroelectric film,
wherein said upper electrode includes an AOₓ-type conductive oxide film formed on said ferroelectric film and an “A” metal film formed on said AOₓ-type conductive oxide film, and
said “A” metal is a noble metal selected from among Ir, Ru, Rh, Pt, Os and Pd.

2. The ferroelectric memory according to claim 1, wherein an ABOₓ perovskite-type conductive oxide film (“B” refers to a metal) is further formed between said ferroelectric film and said AOₓ-type conductive oxide film.

3. The ferroelectric memory according to claim 1, wherein said AOₓ-type conductive oxide film has a crystal structure.

4. The ferroelectric memory according to claim 2, wherein said AOₓ-type conductive oxide film has a crystal structure.

5. A ferroelectric memory that stores information by using a hysteresis characteristic of a ferroelectric, comprising:
a semiconductor substrate;
a lower electrode formed above said semiconductor substrate;
a ferroelectric film formed on said lower electrode; and
an upper electrode formed on said ferroelectric film,
wherein said upper electrode includes a first AOₓ-type conductive oxide film formed on said ferroelectric film and a second AOₓ-type conductive oxide film formed on said first AOₓ-type conductive oxide film,
said second AOₓ-type conductive oxide film has a higher “A” metal concentration than said first AOₓ-type conductive oxide film, and
said “A” metal is a noble metal selected from among Ir, Ru, Rh, Pt, Os and Pd.

6. The ferroelectric memory according to claim 5, wherein an ABOₓ perovskite-type conductive oxide film (“B” refers to a metal) is further formed between said ferroelectric film and said first AOₓ-type conductive oxide film.

7. The ferroelectric memory according to claim 5, wherein said first AOₓ-type conductive oxide film and said second AOₓ-type conductive oxide film have a crystal structure.

8. The ferroelectric memory according to claim 6, wherein said first AOₓ-type conductive oxide film and said second AOₓ-type conductive oxide film have a crystal structure.

9. A method of manufacturing a ferroelectric memory that stores information by using a hysteresis characteristic of a ferroelectric, comprising:
forming a lower electrode above a semiconductor substrate;
forming a ferroelectric film on said lower electrode; and
forming an upper electrode on said ferroelectric film by forming an AOₓ-type conductive oxide film by chemical sputtering,
wherein an “A” metal is a noble metal selected from among Ir, Ru, Rh, Pt, Os and Pd, and
sputtering of the “A” metal is carried out in a same chamber as the chamber used for said chemical sputtering after said chemical sputtering.

10. The method of manufacturing a ferroelectric memory according to claim 9, wherein said upper electrode is formed by forming said AOₓ-type conductive oxide film on said ferroelectric film by chemical sputtering and forming an “A” metal film on said AOₓ-type conductive oxide film by sputtering.

11. The method of manufacturing a ferroelectric memory according to claim 9, wherein said AOₓ-type conductive oxide film is crystallized by heating.

12. The method of manufacturing a ferroelectric memory according to claim 10, wherein said AOₓ-type conductive oxide film is crystallized by heating.

13. The method of manufacturing a ferroelectric memory according to claim 9, wherein an ABOₓ perovskite-type conductive oxide film (“B” refers to a metal) is formed between said ferroelectric film and said AOₓ-type conductive oxide film.

14. A method of manufacturing a ferroelectric memory that stores information by using a hysteresis characteristic of a ferroelectric, comprising:
forming a lower electrode above a semiconductor substrate;
forming a ferroelectric film on said lower electrode; and
forming an upper electrode on said ferroelectric film by forming a first AOₓ-type conductive oxide film on said ferroelectric film and forming a second AOₓ-type conductive oxide film on said first AOₓ-type conductive oxide film
wherein an “A” metal is a noble metal selected from among Ir, Ru, Rh, Pt, Os and Pd.

15. The method of manufacturing a ferroelectric memory according to claim 14, wherein said upper electrode is formed by forming said first AOₓ-type conductive oxide film on said ferroelectric film by chemical sputtering and forming said second AOₓ-type conductive oxide film on said first AOₓ-type conductive oxide film by chemical sputtering.

16. The method of manufacturing a ferroelectric memory according to claim 14, wherein said first AOₓ-type conductive oxide film is crystallized by heating.

17. The method of manufacturing a ferroelectric memory according to claim 15, wherein said first AOₓ-type conductive oxide film is crystallized by heating.

18. The method of manufacturing a ferroelectric memory according to claim 14, wherein an ABOₓ perovskite-type conductive oxide film (“B” refers to a metal) is formed between said ferroelectric film and said first AOₓ-type conductive oxide film.
